(19) United States
(12) Patent Application Publication
(10) Pub. No.: US 2013/0092491 A1
(43) Pub. Date: Apr. 18, 2013

(54) POWER SUPPLY APPARATUS FOR ON-LINE ELECTRIC VEHICLE, METHOD FOR FORMING SAME AND MAGNETIC FIELD CANCELATION APPARATUS

(71) Applicants: Nam Pyo Suh, Daejeon (KR); Soon Heung Chang, Daejeon (KR); Dong Ho Cho, Seoul (KR); Jung Goo Cho, Suwon (KR); Chun Taek Rim, Daejeon (KR); Gu Ho Jeong, Daejeon (KR); Kyung Hun Lee, Daejeon (KR); Bo Yune Song, Seoul (KR); Yang Jin Cho, Daejeon (KR); Chae Hun Lim, Daejeon (KR); Jong Woo Kim, Daejeon (KR); Young Dong Son, Daejeon (KR); Joo Young Choi, Daejeon (KR); Ji Chul Jang, Daejeon (KR); In Lee, Daejeon (KR); Eun Ho Kim, Daejeon (KR); Myung Koo Kang, Daejeon (KR)

(72) Inventors: Nam Pyo Suh, Daejeon (KR); Soon Heung Chang, Daejeon (KR); Dong Ho Cho, Seoul (KR); Jung Goo Cho, Suwon (KR); Chun Taek Rim, Daejeon (KR); Gu Ho Jeong, Daejeon (KR); Kyung Hun Lee, Daejeon (KR); Bo Yune Song, Seoul (KR); Yang Jin Cho, Daejeon (KR); Chae Hun Lim, Daejeon (KR); Jong Woo Kim, Daejeon (KR); Young Dong Son, Daejeon (KR); Joo Young Choi, Daejeon (KR); Ji Chul Jang, Daejeon (KR); In Lee, Daejeon (KR); Eun Ho Kim, Daejeon (KR); Myung Koo Kang, Daejeon (KR)

(73) Assignee: Korea Advanced Institute of Science and Technology, Daejeon (KR)

(21) Appl. No.: 13/501,691

(22) PCT Filed: Oct. 18, 2010
(86) PCT No.: PCT/KR2010/007139

§ 371 Date: Jan. 2, 2013

(30) Foreign Application Priority Data
Oct. 16, 2009 (KR) 10-2009-0098982
Dec. 16, 2009 (KR) 10-2009-0125235
Dec. 30, 2009 (KR) 10-2009-0134968

(51) Int. Cl. B60L 5/00; F16L 1/028; H05K 9/00

(52) U.S. Cl. CPC B60L 5/005; H05K 9/0075; F16L 1/028
USPC 191/10; 174/396; 405/184.4

(57) ABSTRACT

A power supply apparatus is for supplying power to an electric vehicle by a magnetic induction mechanism. The apparatus includes a power supply structure including a multiple number of power supply rail modules connected in a forward road direction, each power supply rail module including at least one power supply line passage elongated in the forward road direction, a power supply core of a lattice structure provided below the power supply line passage, and a concrete structure incorporating the power supply line passage and the power supply core; at least one power supply line accommodated in the power supply line passage in the forward road direction and surrounded by an insulating pipe; and at least one common line provided in the forward road direction and surrounded by an insulating pipe, for supplying power to the power supply apparatus.

### TECHNICAL FIELD

The present invention relates to a power supply apparatus for an on-line electric vehicle, a method for forming same and a magnetic field cancelation apparatus. More particularly, the present invention relates to a power supply apparatus for an on-line electric vehicle capable of being protected from deformation and damage of a road by being buried in the road while its power supply lines and power supply cores are embedded in a concrete structure. Further, the present invention also relates to a method for forming the power supply apparatus for the on-line electric vehicle and a magnetic field cancelation apparatus for canceling a magnetic field emitted from a common line of the power supply apparatus.

### BACKGROUND ART

Recently, tremendous attention is being paid to an electric vehicle and a hybrid vehicle as an environment friendly means of transportation. An electric vehicle and a plug-in hybrid vehicle developed so far, however, need to be connected to an external power feeder through a plug or the like for a long time to charge its battery. Further, the vehicles can travel only a very limited distance after they are charged one time. Thus, an on-line electric vehicle capable of charging a battery by magnetic induction while travelling on a power supply road is recently attracting attention as an alternative to a conventional electric vehicle using battery.

In the on-line electric vehicle, construction of a power supply road (or a power supply rail) for supplying electricity to the electric vehicle is required. To function as a power supply road, a power supply apparatus including power supply cores and power supply lines needs to be buried in the road while a certain distance from the ground is maintained.

In a conventional power supply apparatus for an on-line electric vehicle proposed so far, power supply cores and power supply lines are buried directly on the road. Accordingly, when deformation and damage of the road are caused as the electric vehicle runs on the road or when the road expand or contract due to heat absorption or dissipation or when moisture invades the road in the rain or the like, the operation of the power supply road may become very unstable. One of examples of the power supply apparatus for an on-line electric vehicle is disclosed in PCT Application No. PCT/KR2010/001376, filed on Mar. 5, 2010, entitled “ULTRA SLIM POWER SUPPLY DEVICE AND POWER ACQUISITION DEVICE FOR ELECTRIC VEHICLE”, which is assigned to the assignee of the present invention.

Furthermore, since plate-type power supply cores have been used, asphalt on the top surface and below the rear surface of the cores may not be adhered strongly, and, thus, the effect of fixing the power supply cores under the road has been very weak. Although using a power supply core of a lattice structure has been proposed as a solution to this problem, the effect of enhancing fixation of the power supply core under the road has not been so great because a width of each core blade of the core is relatively large as compared to a distance between core blades.

Moreover, in a conventional method for burying the power supply apparatus, all the power supply cores and power supply lines are installed together after the road is dug in, and the road is covered with asphalt or the like afterward. Thus, the installation process has been very troublesome.

Besides, a magnetic field generated in the power supply road has raised safety issue due to exposure to electromagnetic waves.

### DISCLOSURE OF INVENTION

### Technical Problem

In view of the foregoing, the present invention provides a power supply apparatus capable of stably supplying power to an on-line electric vehicle travelling on a road by being buried under the road while its power supply cores and power supply lines are embedded and protected in a concrete structure.

Further, the present invention also provides a method for forming the power supply apparatus on a module unit of a preset length.

Furthermore, the present invention also provides a magnetic field cancelation apparatus capable of canceling an electromagnetic field (EMF) emitted from a common line of the power supply apparatus.

### Solution to Problem

In accordance with one aspect of the present disclosure, there is provided a power supply apparatus for supplying power to an electric vehicle by a magnetic induction mechanism, the apparatus including:

a power supply structure including a multiple number of power supply rail modules connected in a forward road direction, each power supply rail module including at least one power supply line passage elongated in the forward road direction, a power supply core of a lattice structure provided below the power supply line passage, and a concrete structure incorporating the power supply line passage and the power supply core;

at least one power supply line accommodated in the power supply line passage in the forward road direction and surrounded by an insulating pipe; and at least one common line provided in the forward road direction and surrounded by an insulating pipe, for supplying power to the power supply apparatus.

In accordance with a second aspect of the present invention, there is provided a method for forming the power supply apparatus for an electric vehicle, the method including:

fabricating a multiple number of power supply rail modules including at least one power supply line passage elongated in the forward road direction, a power supply core of a lattice structure provided below the power supply line passage and a concrete structure incorporating the power supply line passage and the power supply core;

forming grooves of a preset depth in a road in the forward road direction so as to accommodate the power supply rail modules in the grooves; arranging the multiple number of power supply rail modules in the grooves one after another;

inserting at least one power supply line surrounded by an insulating pipe into the power supply line passage in the forward road direction; and

covering the power supply rail modules with asphalt.

In accordance with a third aspect of the present invention, there is provided a method for forming a power supply apparatus for an electric vehicle, the power supply apparatus including at least one power supply line, a power supply core assembly and at least one common line, the method including:

forming a cut-out section of a certain width and a certain depth in a road; installing a power supply rail module including a power supply line pipe for accommodating the power supply line, the power supply core assembly and a common line pipe for accommodating the common line;

installing a multiplicity of power supply rail modules in the cut-out section in a forward road direction by repeating the process of installing the power supply rail module; and

pouring and curing concrete in the power supply rail modules.

In accordance with a fourth aspect of the present invention, there is provided a magnetic field cancelation apparatus for a power supply apparatus for an electric vehicle, the power supply apparatus including at least one power supply line buried in a road and elongated in a lengthwise direction of the road, a power supply core provided below the power supply line while being electrically insulated from the power supply line, and a common line provided below the power supply core, the magnetic field cancelation apparatus including:

a frame member; and

a coil member having a plurality of coils, each coil being wound around the frame member and forming a closed loop, wherein the magnetic field cancelation apparatus is placed on the common line to cancel an electromagnetic field emitted from the common line.

### Advantageous Effects of Invention

In accordance with the present invention, the power supply apparatus buried in the road can be normally operated while being embedded and protected in the concrete structure even in case the road is deformed or damaged due to running of the electric vehicle, temperature, rain, and so forth. Thus, the power supply apparatus is capable of stably supplying power to the electric vehicle travelling on the road.

### BRIEF DESCRIPTION OF DRAWINGS

The above and other aspects and features of the present invention will become apparent from the following description of embodiments, given in conjunction of the accompanying drawings, in which:

FIG. 1 illustrates a schematic configuration of a power supply rail module of a power supply apparatus in accordance with an embodiment of the present invention;

FIG. 2 is a cross sectional view (front view) of the power supply apparatus installed under a road by using the power supply rail module in accordance with the embodiment of the present invention, wherein the figure is taken along a direction perpendicular to a forward road direction;

FIG. 3 provides a cross sectional view (side view) of the power supply apparatus installed under the road by using the power supply rail module of FIG. 2, wherein the figure is taken along a direction parallel to the forward road direction;

FIG. 4 is a front view of a power supply apparatus installed under a road by using a power supply rail module in accordance with another embodiment of the present invention;

FIG. 5 sets forth a front view of a power supply apparatus installed under a road by using a power supply rail module in accordance with still another embodiment of the present invention;

FIG. 6 presents a front view of a power supply apparatus installed under a road by using a power supply rail module in accordance with still another embodiment of the present invention;

FIG. 7 depicts a front view of an embodiment of a power supply apparatus prepared by pouring and curing concrete in a road dug in by a certain depth;

FIG. 8 provides a front view of another embodiment of a power supply apparatus prepared by pouring and curing concrete in a road dug in by a certain depth;

FIG. 9 is a front view of still another embodiment of a power supply apparatus prepared by pouring and curing concrete in a road dug in by a certain depth;

FIG. 10 depicts a front view of an embodiment of a deformation absorbing member;

FIG. 11 sets forth a front view of another embodiment of a deformation absorbing member;

FIG. 12 is across sectional view of a holding jointer mold used in a forming method for a power supply apparatus in accordance with an embodiment of the present invention;

FIG. 13 is a diagram for describing a pipe assembly used in the forming method for the power supply apparatus in accordance with the embodiment of the present invention;

FIG. 14 is a perspective view of a power supply core assembly used in the forming method for the power supply apparatus in accordance with the embodiment of the present invention;

FIG. 15 is a perspective view of a fixing jointer mold used in the forming method for the power supply apparatus in accordance with the embodiment of the present invention;

FIG. 16 presents a diagram for describing a process of forming a cut-out section in a road in the forming method for the power supply apparatus in accordance with the embodiment of the present invention;

FIGS. 17a and 17b set forth diagrams for describing a process of installing holding jointer mold in the forming method for the power supply apparatus in accordance with the embodiment of the present invention, in which FIG. 17a is a perspective view and FIG. 17b is a front view;

FIGS. 18a and 18b present diagrams for describing a process of installing a common line pipe assembly in the forming method for the power supply apparatus in accordance with the embodiment of the present invention, in which FIG. 18a is a perspective view and FIG. 18b is a front view;

FIGS. 19a and 19b are diagrams for describing a process of installing the power supply core assembly in the forming method for the power supply apparatus in accordance with the embodiment of the present invention, in which FIG. 19a is a perspective view and FIG. 19b is a front view;

FIGS. 20a and 20b are diagrams for describing a process of installing a power supply line pipe assembly in the forming method for the power supply apparatus in accordance with the embodiment of the present invention, in which FIG. 20a is a perspective view and FIG. 20b is a front view;

FIGS. 21a and 21b provide diagrams for describing a process of installing a fixing jointer mold in the forming method for the power supply apparatus in accordance with the embodiment of the present invention, in which FIG. 21a is a perspective view and FIG. 21b is a front view;

FIGS. 22a and 22b set forth diagrams for describing a process of installing a mold-fixing clip in the forming method for the power supply apparatus in accordance with the embodiment of the present invention, in which FIG. 22a is a perspective view and FIG. 22b is a front view;

FIG. 23 depicts a diagram for describing a process of pouring concrete in the forming method for the power supply apparatus in accordance with the embodiment of the present invention;

FIG. 24 is a cross sectional view of a power supply apparatus including a magnetic field cancelation apparatus in accordance with an embodiment of the present invention;

FIG. 25 sets forth a perspective view of a frame member of the magnetic field cancelation apparatus in accordance with the embodiment of the present invention;

FIG. 26 presents a front view of the frame member of the magnetic field cancelation apparatus in accordance with the embodiment of the present invention;

FIG. 27 is a side view of the frame member of the magnetic field cancelation apparatus in accordance with the embodiment of the present invention;

FIG. 28 provides a front view of the magnetic field cancelation apparatus in accordance with the embodiment of the present invention;

FIG. 29 illustrates a side view of the magnetic field cancelation apparatus in accordance with the embodiment of the present invention;

FIG. 30 shows a perspective view of the magnetic field cancelation apparatus in accordance with the embodiment of the present invention;

FIG. 31 is a front view of a magnetic field cancelation apparatus in accordance with another embodiment of the present invention;

FIG. 32 is a side view of the magnetic field cancelation apparatus in accordance with another embodiment of the present invention;

FIG. 33 is a plane view of the magnetic field cancelation apparatus in accordance with another embodiment of the present invention; and

FIG. 34 is a plane view showing a configuration in which a multiple number of magnetic field cancelation apparatuses are arranged in a row.

### BEST MODE FOR CARRYING OUT THE INVENTION

Hereinafter, embodiments of the present invention will be described in detail with reference to the accompanying drawings, which form a part hereof.

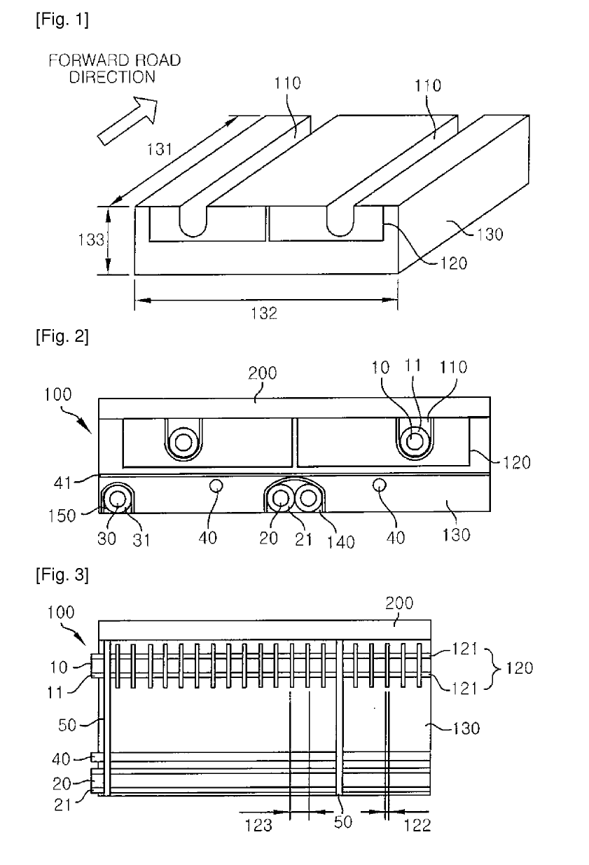

FIGS. 1 to 11 are diagrams for describing power supply apparatuses in accordance with the present invention.

FIG. 1 illustrates a schematic configuration of a power supply rail module 100 of a power supply apparatus in accordance with an embodiment of the present invention.

The power supply rail module 100 includes a pair of power supply line passages 110 accommodating power supply lines elongated in a forward road direction; a power supply core 120 of a lattice structure arranged under the power supply line passages 110; and a concrete structure 130 incorporating the power supply line passages 110 and the power supply core 120. In the figure, a length 131 of the power supply rail module 100 parallel to the forward road direction, a width 132 perpendicular to the forward road direction and a vertical height 133 are indicated.

For installation and formation of the power supply apparatus including the power supply rail module 100, a road is first dug in by a certain depth, and a plurality of power supply rail modules 100 is arranged on the road while being connected with each other in series in a direction parallel to the forward road direction. Then, the power supply lines are inserted in the power supply line passages 110 in the direction parallel to the forward road direction and are covered with asphalt. In this way, since the power supply cores, the power supply lines and the like are protected in a concrete structure without receiving a load from the road directly, the power supply apparatus buried in the road can be normally operated even in case deformation and damage of the road is caused due to running of an electric vehicle, temperature, rain, and the like. Thus, the power supply apparatus may be capable of stably supplying power to the electric vehicle travelling on the road.

Further, by configuring the concrete structure 130 as a module in this way, the installation and formation of the power supply apparatus for the electric vehicle can be very simplified.

FIG. 2 is a cross sectional view (front view) of the power supply apparatus installed under the road by using the power supply rail module 100 in accordance with the embodiment of the present invention. The figure is taken along a direction perpendicular to a forward road direction.

Each power supply line 10 is protected by an insulating pipe 11 so as to prevent an electric discharge to the outside and is inserted in the power supply line passage 110 above the power supply core 120.

The power supply rail module 100 of FIG. 2 further includes a common line passage 140 for accommodating a common line 20 for supplying high frequency power to the power supply apparatus; and a communication line passage 150 for accommodating a communication line for communications between devices such as various electric vehicle sensors buried in the road or between the devices and the outside. The common line 20 and the communication line 30 are protected by insulating pipes 21 and 31, respectively. Further, vinyl may be wound around the insulating pipes 11, 21 and 31 several times to improve waterproofing effect.

The insulating pipes 11, 21 and 31 may be made of a PVC material or may be made of a bellows pipe instead of a hard PVC pipe. When cables are inserted into the insulating pipes 11, 21 and 31, the pipes may be dropped from a high building by using gravity, and the cables may be inserted into the pipe by being dropped gravitationally. Thus, as compared to a case of inserting the pipes and the cables horizontally in the ground, difficulty in insertion or damage on surfaces of the pipes and the cables due to friction may be prevented. Therefore, the cables can be prevented from being rendered useless as a result of failure in waterproofing.

Meanwhile, FIG. 2 shows an example in which the common line 20 is located in a center position.

By inserting a pair of steel reinforcements 40 under the power supply core 120 at left and right sides of the common line 20 located at a center of a lower portion of the concrete structure 130 in the forward road direction, the concrete structure 130 can be reinforced. In this case, if the common line 20 and each steel reinforcement 40 are spaced apart from each other only by about 5 cm, the amount of heat generation due to magnetic induction may not be so great. The steel reinforcements 40 provided in the forward road direction may reduce damage of the concrete structure 130 and crack generation due to a faulting caused by ground sinkage. Further, another steel reinforcement 41 may be inserted under the power supply core 120 in a direction perpendicular to the forward road direction. This steel reinforcement 41 may be spaced apart from the steel reinforcements 40 arranged in the forward road direction by about several centimeters or more so as to prevent generation of a loop current due to magnetic induction. If the installation of the power supply apparatus is completed, the top of the apparatus may be covered with asphalt 200.

Meanwhile, the power supply apparatus may further include an inverter (not shown) for converting a DC power from an external power supply (not shown) into an AC power. The AC power converted by the inverter may be supplied to the power supply line 10.

FIG. 3 is a cross sectional view (side view) of the power supply apparatus installed under the road by using the power supply rail module of FIG. 2, and the figure is taken along a direction parallel to the forward road direction.

As can be seen from FIG. 3, the power supply core 120 is configured to have a lattice structure. The power supply core 120 of the lattice structure includes a plurality of frames (hereinafter referred to as “core blades”) 121 arranged in a lattice pattern. A forward-road-directional width 122 of each core blade 121 forming the lattice pattern of the power supply core 120 may be equal to or less than about ⅓ of a distance 123 between the core blades and, desirably, the width 122 may range from about ⅕ to about 1/20 of the distance 123. In this way, by using the power supply core 120 of the lattice structure including such thin core blades, cost can be reduced greatly, and an area in which the inside and the outside of the power supply core 120 are abutted can be maximized, so that the power supply core 120 can be firmly fixed in the concrete structure 130. Even if the thickness 122 of each core blade of the power supply core 120 in the forward road direction is reduced, a magnetic field around the power supply core 120 may be absorbed due to high magnetic permeability of the power supply core 120. Thus, almost the same effect of power transmission may be achieved.

Further, the steel reinforcements 40 for reinforcing the concrete structure are inserted in the forward road direction as stated above.

Furthermore, in the embodiment shown in FIG. 3, deformation absorbing members 50 are additionally inserted. The deformation absorbing members 50 may be arranged at a distance of about 4 m to about 6 m in the forward road direction. The deformation absorbing members 50 may absorb deformation of the concrete structure 130, e.g., thermal deformation due to a temperature variation and thus prevent a damage of concrete. The deformation absorbing members 50 will be described in more detail later with reference to FIGS. 9 and 10.

As for a U-shaped power supply core, it may be desirable to bury upright portions of the power supply core completely under a road without protruding above a road surface even in case that the U-shaped power supply core is buried directly in an asphalt road as well as in case that it is protected in the concrete structure, as shown in FIG. 3.

Although FIG. 3 shows an example in which the power supply core 120 has the ‘U’-shape, the power supply core 120 may also be configured to have a lattice structure even in case that it is of a plate type.

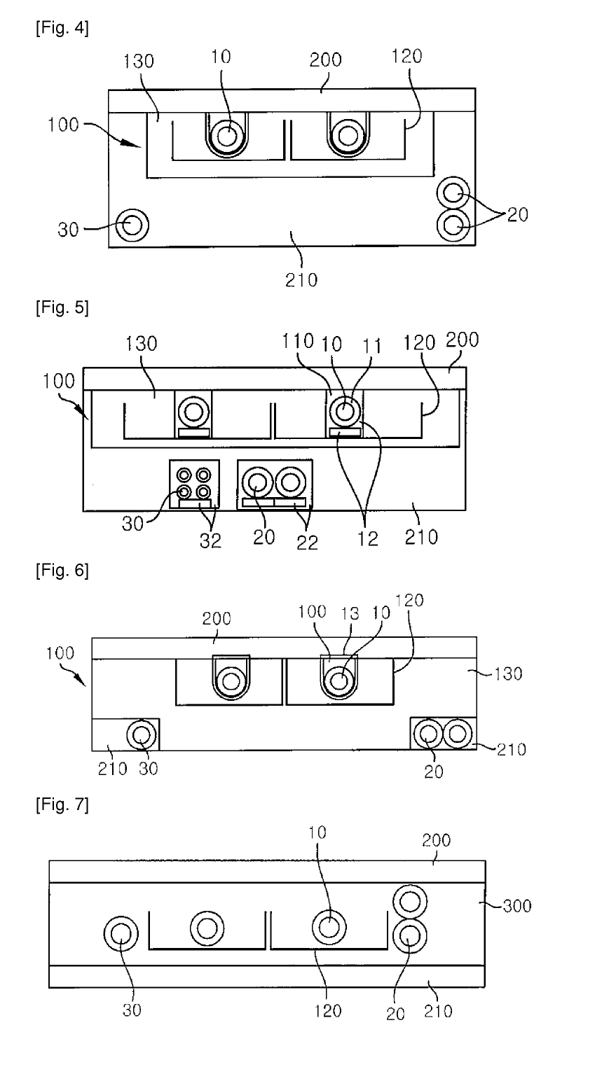

FIG. 4 is a front view of a power supply apparatus installed under a road by using a power supply rail module 100 in accordance with another embodiment of the present invention.

In the embodiment shown in FIG. 4, a common line 20 and a communication line 30 are provided outside the power supply rail module 100, and the common line 20 is located in a side position, not in a center position, unlike in FIG. 2. In this case, the common line 20 and the communication line 30 may be first buried in asphalt 210 under the road, and, then, the power supply apparatus may be installed and formed by using the power supply rail module 100.

FIG. 5 is a front view of a power supply apparatus installed under a road by using a power supply rail module 100 in accordance with still another embodiment of the present invention.

In the embodiment of FIG. 5, a power supply line 10 surrounded by an insulating pipe 11 is inserted in a power supply line passage 110 having a slight clearance space, and the clearance space within the power supply passage 110 is filled with a FRP (Fiberglass Reinforced Plastic) 12. With this configuration, a clearance for expansion and contraction of the insulating pipe due to a temperature variation is allowed while the power supply line 10 is still protected by both the insulating pipe 11 and the FRP 12. Such a dual protection structure may also be applied to a common line 20 and a communication line 30 by using FRPs 22 and 23, respectively, as illustrated in the figure.

FIG. 6 is a front view of a power supply apparatus installed under a rod by using a power supply rail module 100 in accordance with still another embodiment of the present invention.

In the embodiment of FIG. 6, a concrete structure 130 has a ‘T’-shaped cross section, and a common line 20 and a communication line 30 are buried in asphalts 210 outside the concrete structure 130. Further, the top of the power supply line passage 110 is covered with FRP 13.

The power supply apparatuses using the power supply rail modules 100 of FIGS. 2 to 6 may be installed as follows. A plurality of power supply rail modules 100 is fabricated in advance so that each of the power supply rail modules 100 includes at least one power supply line passage 110 elongated in a forward road direction; a power supply core 120 of a lattice structure provided below the power supply line passage 110; and a concrete structure 130 incorporating the power supply line passage 110 and the power supply core 120. Then, grooves of a certain depth are formed in a road in the forward road direction so as to bury the power supply rail modules 100 therein. The plurality of power supply rail modules 100 are arranged in the grooves one after another, and at least one power supply line 10 surrounded by an insulating pipe 11 is inserted in the power supply line passage 110 in the forward road direction. Then, the power supply rail modules 100 are covered with asphalt 200. Meanwhile, a power supply rail module 100 in accordance with the present invention may also be prepared by arranging the power supply core 110 and the power supply line 10 in a road dug in by a certain depth and then pouring and curing concrete in the road.

FIG. 7 is a front view showing an embodiment of power supply apparatus prepared by pouring and curing concrete in a road dug in by a certain depth. That is, asphalt is dug in from the road, and after a power supply apparatus including a power supply core 120 and a power supply line 10 are buried therein, concrete 300 is poured and cured, and, then, asphalt is covered thereon. A common line 20 and a communication line 30 are located at side positions within the concrete 300.

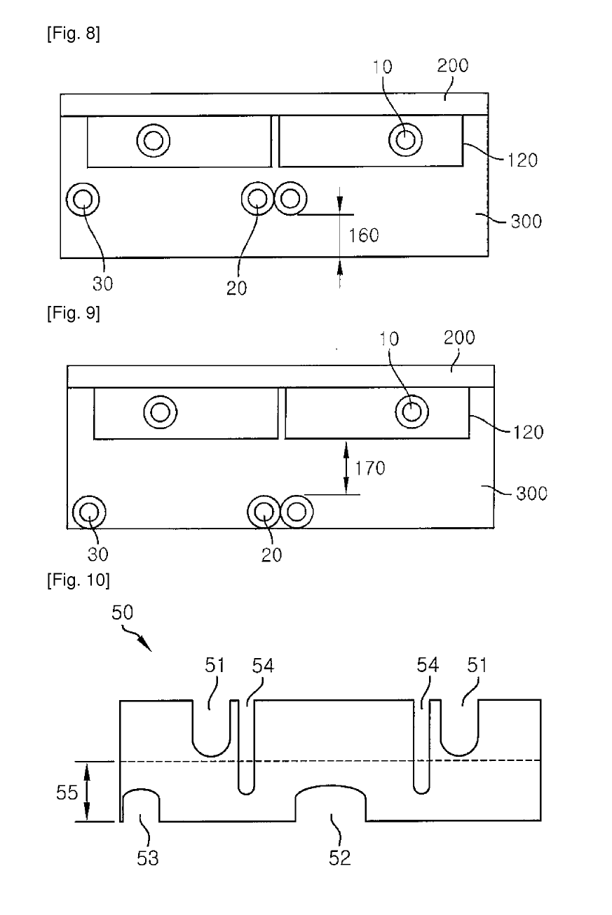

FIG. 8 is a front view showing another embodiment of a power supply apparatus prepared by pouring and curing concrete in a rod dug in by a certain depth. That is, as in the case of FIG. 7, asphalt is dug in from the road, and after a power supply apparatus including a power supply core 120 and a power supply line 10 are buried therein, concrete 300 is poured and cured, and, then, asphalt is covered thereon. In the embodiment of FIG. 8, a distance 160 between a common line 20 and the bottom asphalt is large enough to stand a load of about 10 tons or more.

FIG. 9 is a front view showing still another embodiment of power supply apparatus prepared by pouring and curing concrete in a rod dug in by a certain depth. That is, as in the case of FIG. 8, asphalt is dug in from the road, and after a power supply apparatus including a power supply core 120 and a power supply line 10 are buried therein, concrete 300 is poured and cured, and, then, asphalt is covered thereon. In the embodiment of FIG. 9, a distance 170 between a power supply core 120 and the top of a common line 20 is large enough to stand a load of about 10 tons or more.

Though not shown in the embodiments of FIGS. 7 to 9, the common line 20 may be buried in a bottom portion or in a side portion of concrete before the concrete is cured.

FIG. 10 is a front view showing an embodiment of a deformation absorbing member 50. The deformation absorbing member 50 may include power supply line grooves 51 for accommodating power supply lines 10 and insulating pipes 11 protecting the power supply lines 10; a common line passage 52 for accommodating a common line 20 and an insulating pipe 21 protecting the common line 20; a communication groove 53 for accommodating a communication line 30 and an insulating pipe 31 protecting the communication line 30; and steel reinforcement grooves 54 for accommodating steel reinforcements 40. In the figure, the deformation absorbing member 50 has a structure for supporting the insulating pipes or the steel reinforcements from below.

The deformation absorbing member 50 can carry out a deformation absorbing function both in power supply roads shown in FIGS. 2 to 6 using the power supply rail module 100 of FIG. 1 and in the power supply apparatuses in accordance the embodiments of FIGS. 7 to 9 in which concrete is poured and cured after the road is dug in and the power supply apparatuses are buried therein. Especially, in case of the power supply apparatuses of FIGS. 7 to 9, the deformation absorbing member 50 may have a function as a mold for pouring and curing concrete therein as well as a function of absorbing thermal deformation or the like.

The structures as disclosed in FIGS. 7 to 9 in which concrete 300 is poured and cured after a power supply apparatus is installed may be formed through the steps of (1) installing a common line 20 and a communication line 30 first; (2) installing a deformation absorbing member 50; (3) pouring concrete only in an area from the bottom to where a power supply core 120 is to be situated; (4) waiting till the concrete is cured to a certain degree; (5) positioning the power supply core 120; (6) installing a power supply line 10; (7) pouring concrete up to a height where the power supply core 120 is hidden from view; (8) waiting till the concrete is cured sufficiently; and (9) covering the top of the structure with asphalt.

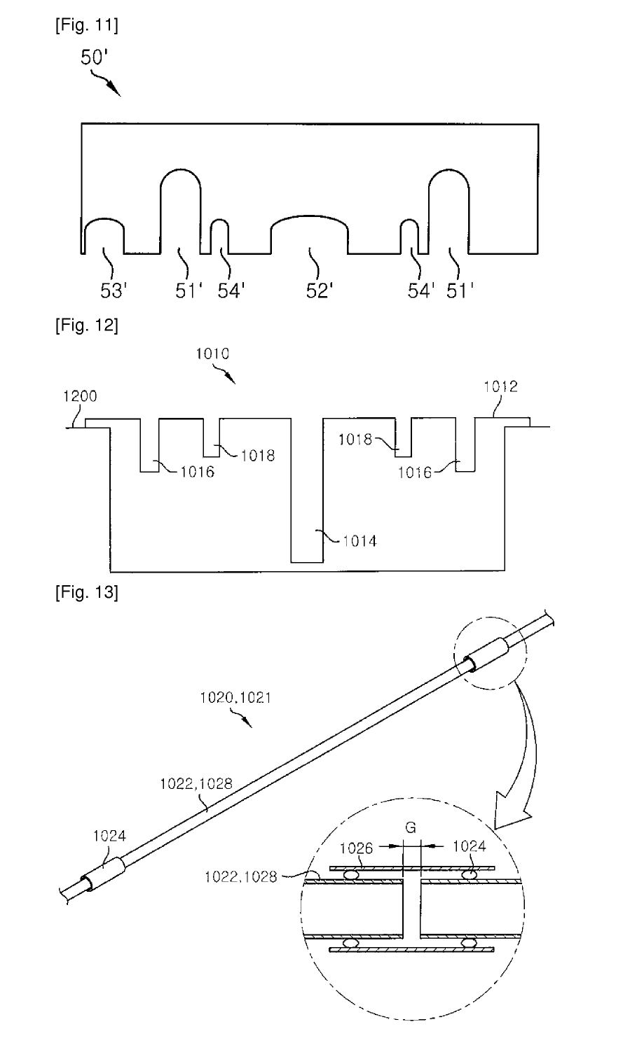

FIG. 11 is a front view showing another embodiment of a deformation absorbing member 50′. The deformation absorbing member may includes power supply line grooves 51′ for accommodating power supply lines 10 and insulating pipes 11 protecting the power supply lines 10; a common line passage 52′ for accommodating a common line 20 and an insulating pipe 21 protecting the common line 20; a communication groove 53′ for accommodating a communication line 30 and an insulating pipe 31 protecting the communication line 30; and steel reinforcement grooves 54′ for accommodating steel reinforcements 40. In the figure, the deformation absorbing member 50′ has a structure for pressing the insulating pipes or the steel reinforcements from above.

As described above, FIGS. 10 and 11 illustrate different types of deformation absorbing members 50 and 50′. Although it may be possible to use either one of the two types of deformation absorbing members 50 and 50′, it may also be possible to install both deformation absorbing members 50 in pair, thus allowing the deformation absorbing member 50 of FIG. 10 to support the insulating pipes or the steel reinforcements from below while the deformation absorbing member 50′ of FIG. 11 presses them from above.

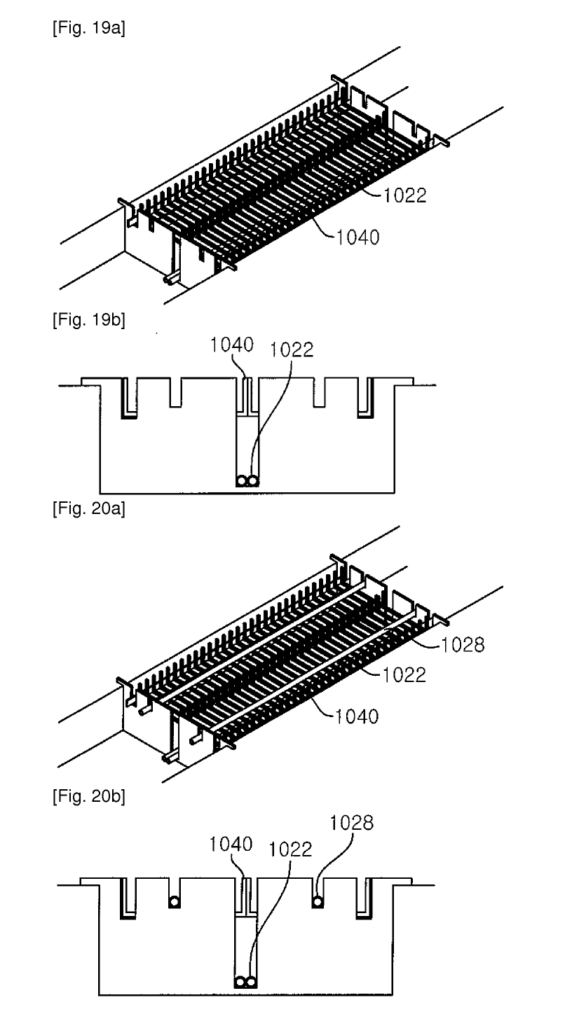

FIGS. 12 to 23 are diagrams for describing a concrete-pour-type forming method for a power supply apparatus in accordance with an embodiment of the present invention.

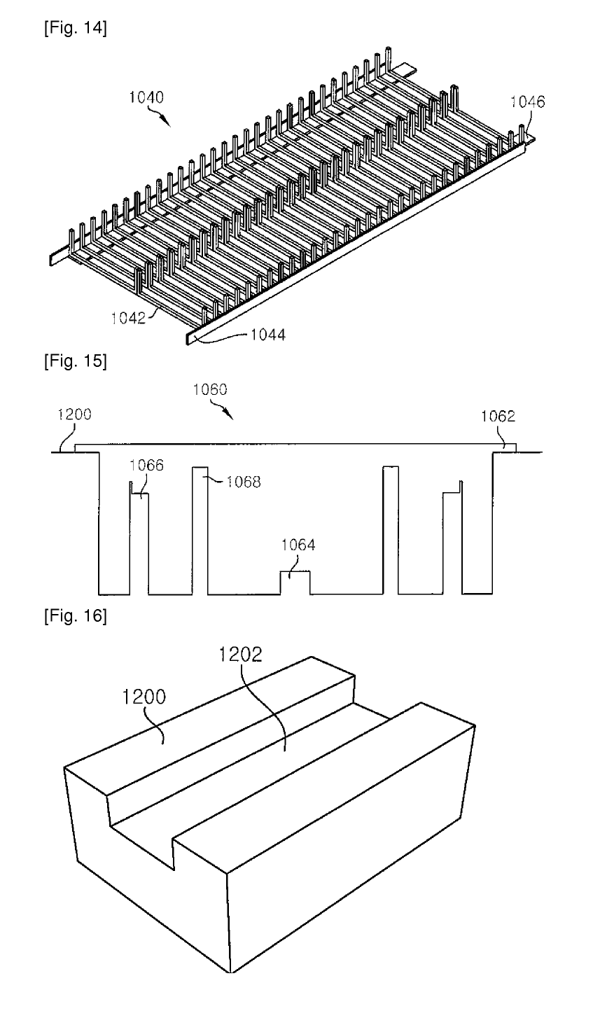

FIG. 12 is a cross sectional view of a holding jointer mold used in the power supply apparatus forming method in accordance with the embodiment of the present invention, and FIG. 13 is a diagram for describing a pipe assembly used in the power supply apparatus forming method. Further, FIG. 14 is a perspective view of a power supply core assembly used in the power supply apparatus forming method, and FIG. 15 is a cross sectional view of a fixing jointer mold used in the power supply apparatus forming method.

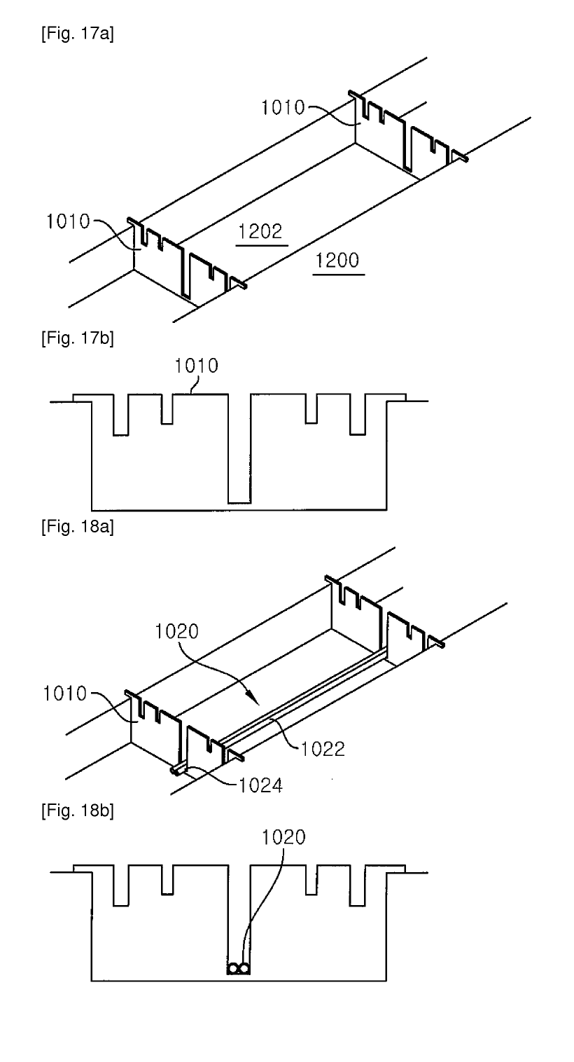

The forming method of the present embodiment may include, as sequentially illustrated in FIGS. 17 to 23, (1) a step of cutting out a road, (2) a step of installing a holding jointer mold, (3) a step of installing a power supply core assembly and a pipe assembly, (4) a step of installing a fixing jointer mold, (5) a step of repeating the steps (2) to (4) for the entire cut-out road section, and (6) a step of pouring concrete.

(1st step: cutting out a road, see FIG. 16)

First, a road in which a power supply road is to be installed is cut out by a preset depth and width. Since a power supply core assembly and a pipe assembly for various cables need to be installed to form a power supply road or a power supply rail, an existing road surface 1200 needs to be cut out to form a cut-out section 1202, as shown in FIG. 16. Further, the power supply road needs to have sufficient durability against a load from a vehicle travelling on the power supply road. Thus, when the existing road surface 1200 is cut out, it may be desirable to cut out or dig in the road surface or ground surface by a sufficient depth in consideration of the durability.

Further, when cutting out or digging in the existing road surface 1200, a center of a lane to be used for a travel of an on-line electric vehicle needs to be dug out so as to face a current collector fixed to a lower part of the on-line electric vehicle. A cutting width may correspond to a width of the current collector, and it may be desirable to set the cutting width to be slightly larger than the width of the power supply core.

Meanwhile, when a concrete pavement is newly formed at a place where there is no existing road, the width of jointer molds would be modified based on the width of a road in which the concrete pavement is to be formed, and the formation of the power supply road may be carried out in the same method as described above.

(2nd step: installing a holding jointer mold, see FIGS. 17a and 17b)

If the cut-out section 1202 is formed by cutting out the existing road surface 1200, holding jointer molds 1010 are installed on the cut-out section 1202 at a certain distance. In the forming method of the present invention, power supply apparatuses are formed on a module unit, and, thus, two holding jointer molds 1010 are respectively installed at both ends of each road section divided by a length of each module.

Meanwhile, for the convenience of installation of the holding jointer mold 1010 and for the convenience of installation of structural parts of the power supply road, the holding jointer mold 1010 may include, as illustrated in FIG. 12, protrusions 1012 for alignment, a groove 1014 for holding a common line pipe, grooves 1016 for holding core assemblies and grooves 1018 for holding power supply line pipes. The protrusions 1012 for alignment may be protruded horizontally at both lateral sides of the holding jointer mold 1010 in a width direction of a road. The protrusions 1012 for alignment are settled on uncut portions of the existing road 1200 and serve to fix the holding jointer mold 1010 while preventing the holding jointer mold 1010 from falling down or being tilted. Further, the protrusions 1012 also function to maintain a relative position of the holding jointer mold 1010 with respect to the existing road 1200. The groove 1014 for holding the common line pipe is formed at a central portion of the holding jointer mold 1010; the grooves 1016 for holding the core assemblies are formed at both left and right sides of the groove 1014 for holding the common line pipe; and the grooves 1018 for holding the power supply line pipes are formed between the groove 1014 for the common line pipe and the grooves 1016 for the core assemblies. These grooves 1014, 1016 and 1018 are elongated from the top of the holding jointer mold 1010 toward the bottom thereof so that the parts (common pipe, power supply core assemblies, power supply line pipes) can be placed therein from above. To elaborate, among the grooves, the groove 1014 for the common line pipe that hardly affects an electric vehicle may be elongated longest (downward), whereas the grooves 1016 for the core assemblies and the grooves 1018 for the power supply line pipes that affect the electric vehicle may be elongated relatively short so as to maintain a relatively short distance from the surface of the power supply road.

Meanwhile, to accommodate a sensor signal line or the like in a lane structure, an additional pipe into which the sensor single line is to be inserted needs to be included in the rail structure, and a groove for this additional pipe needs to be formed in the holding jointer mold 1010 and a fixing jointer mold 1016 to be described later. However, the sensor single line may be installed together with the common line pipe 1022 when necessary.

(3rd step: installing structural parts of the power supply road, see FIGS. 18a to 20)

If the installation of the holding jointer mold 1010 is completed, the structural parts of the power supply road (common pipe, power supply core assemblies and power supply line pipes) are sequentially installed as depicted in FIGS. 18a to 20.

First, the common line pipes 1022 for which the longest groove is provided is installed within the groove 1014 for the common line pipe, and, then, power supply core assemblies 1040 are installed within the grooves 1016 for the power supply core assemblies. Thereafter, power supply line pipes 1028 are installed within the grooves 1018 for the power supply line pipes.

Here, each of the common line pipes 1022 and the power supply line pipes 1028 has a length corresponding to a certain-length unit (or referred to as a module unit) divided by the pair of holding jointer molds 1010. A common line pipe assembly 1020 is formed by connecting a multiple number of common line pipes 1022, and a power supply line pipe assembly 1021 is formed by connecting a multitude of power supply line pipes 1028. These pipe assemblies 1020 and 1021 respectively include couplings 1024 so as to be connected with adjacent pipes 1022 and 1028, as illustrated in FIG. 13. More desirably, the pipe assemblies 1020 and 1021 may include cylindrical couplings 1024 having a diameter larger than those of the pipes 1022 and 1028 and O-rings 1026 provided inside the couplings 1024.

Each of the pipe assemblies 1020 and 1021 connects the same kinds of pipes 1022 and 1028 within the couplings 1024, as shown in FIG. 13. Here, the O-rings 1026 fill up gaps between the couplings 1024 and the pipes 1022 and 1028, thus preventing concrete from reaching the inside of the couplings 1024. Here, in consideration of the fact that most of the pipes 1022 and 1028 are expanded and contracted in a lengthwise direction due to thermal expansion, the pipes need to be installed within the couplings 1024 at a certain gap G maintained therebetween lest their ends should be in contact with each other.

The power supply core assembly 1040 also needs to have a length corresponding to the module length. As depicted in FIG. 14, the power supply core assembly 1040 includes a plurality of power supply cores 1042, a pair of vertical guides 1044 and a pair of horizontal guides 1046. Each power supply core 1042 has a cross section of an ‘E’-shape (in case of a dual type), and a multiple number of power supply cores 1042 is installed at a certain distance in a lengthwise direction of the cut-out section 1202. The vertical guides 1044 are adhered and fixed to both lateral sides of the power supply cores 1042 arranged at the certain distance, and the horizontal guides 1046 are adhered and fixed to bottom surfaces of both lateral ends of the power supply cores 1042. The vertical guides 1044 and the horizontal guides 1046 serve to fix the distance between the power supply cores 1042 and to fix them in place. The vertical guides 1044 and the horizontal guides 1046 are elongated in opposite directions longer than the module length and are held by different jointer molds 1010 and 1060. For example, if the vertical guide 1044 is held by a holding jointer mold 1010 and a fixing jointer mold 1060 of a prior module, the horizontal vehicle 1046 may be held by a holding jointer mold 1010 and a fixing jointer mold 1060 of a posterior module. Such a structure allows the power supply cores 1042 divided by the jointer molds 1010 and 1060 (i.e., power supply cores of prior and posterior modules) to be connected without suffering great interference.

If the installation of the power supply core assembly 1040 is completed, the power supply line pipe 1028 is installed as illustrated in FIG. 13.

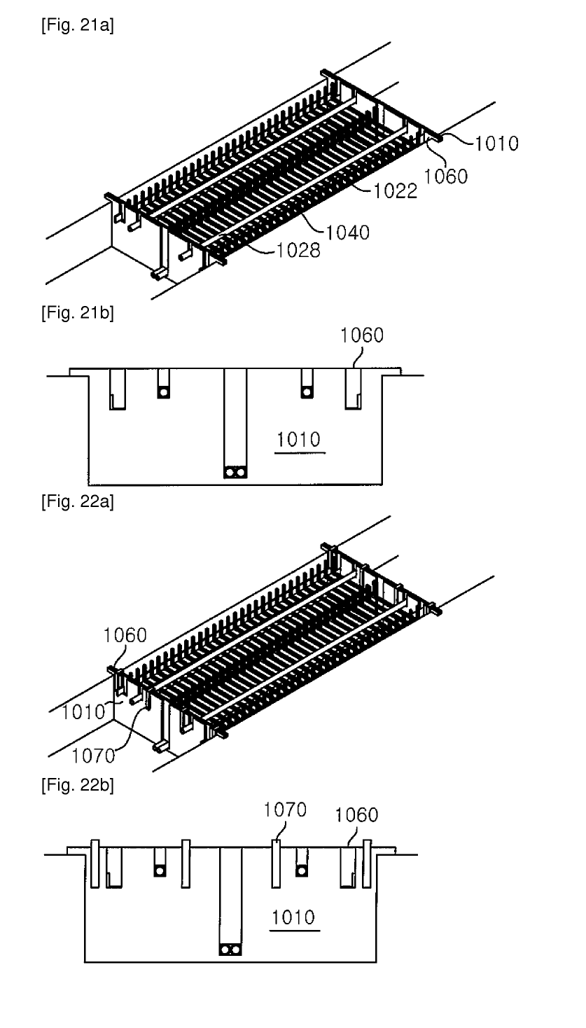

(4th step: installing the fixing jointer mold, see FIGS. 21a and 21b)

If the installation of the common line pipe 1022, the power supply core assembly 1040 and the power supply line pipe 1028 of the power supply apparatus is completed, the fixing jointer mold 1060 is installed.

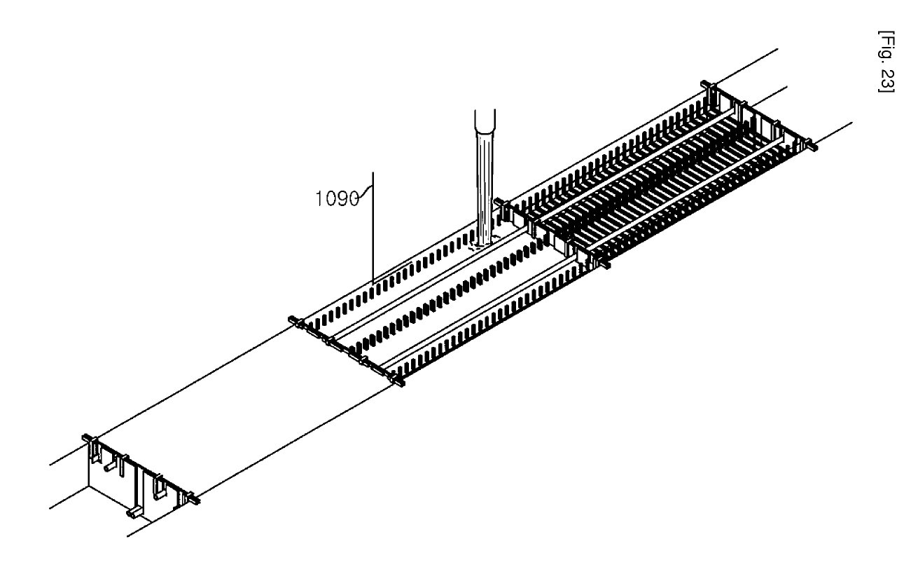

The fixing jointer mold 1060 is fixed by being fitted into the holding jointer mold 1010, and it serves to fix and align the respective structural parts (pipe assemblies 1020 and 1021 and the power supply core assembly 1040). The coupling of the fixing jointer mold 1060 and the holding jointer mold 1010 may be achieved by a mold-fixing clip 1070 of an inverted ‘U’-shape (see FIGS. 22a and 22b).

Meanwhile, for the convenience of installation of the fixing jointer mold 1060 and for the convenience of installation of structural parts of the power supply apparatus, the fixing jointer mold 1060 may include, as illustrated in FIG. 15, protrusions 1062 for alignment, a groove 1064 for fixing a common line pipe, grooves 1066 for fixing core assemblies and grooves 1068 for fixing power supply line pipes. The protrusions 1062 for alignment may be protruded horizontally at both lateral sides of the fixing jointer mold 1060 in the width direction of the road. The protrusions 1062 for alignment are settled on un-cut portions of the existing road 1200 and serve to fix the fixing jointer mold 1060 while preventing the fixing jointer mold 1060 from falling down or being tilted. Further, the protrusions 1062 also function to maintain a relative position of the fixing jointer mold 1060 with respect to the existing road 1200. The groove 1014 for fixing the common line pipe is formed at a central portion of the fixing jointer mold 1060; the grooves 1066 for fixing the core assemblies are formed at both left and right sides of the groove 1064 for fixing the common line pipe; and the grooves 1068 for fixing the power supply line pipes are formed between the groove 1064 for fixing the common line pipe and the grooves 1016 for fixing the core assemblies. These grooves 1064, 1066 and 1068 are elongated from the bottom of the fixing jointer mold 1060 toward the top thereof, in the opposite manner to the grooves 1014, 1016 and 1018, so that the parts (common pipe, power supply core assemblies, power supply line pipes) can be stably fixed by the fixing jointer mold 1060.

(5th step: repeating the 2nd to the 4th step)

If a single power supply rail module for forming a power supply road of a certain length is formed through the above-described processing steps, neighboring power supply rail modules are made in sequence by repeating the 2nd to the 4th step.

(6th step: pouring concrete, see FIG. 23)

Modules for all sections of the power supply road are prepared through the fifth step, concrete is poured as shown in FIG. 23. Then, by inserting an air bubble remover 1090 between a lateral surface of the power supply core 1042 and the cut-out section 1202 and by moving and rotating the air bubble remover 1090, air bubbles under the power supply core assembly 1040 are removed. After the air bubbles are removed, the top surface of the concrete is flattened and sufficiently cured, so that a power supply apparatus is obtained.

Meanwhile, the molds 1010 and 1060 may be made of a wood such as a veneer board, and these molds are not removed after the power supply rail module (structure) is cured so as to prevent block the structure lest a stress of the structure should increase excessively when the structure expands in a lengthwise direction. Additionally, various kinds of cable wiring works and sensor installation works need to be performed to complete the formation of the power supply road, and a clean road surface may be obtained by further curing concrete on top of the previously cured concrete.

The forming method in accordance with the embodiment of the present invention can be summarized as follows.

1st step: forming the cut-out section 1202 by digging out a center of a road by a certain width and a certain depth

2nd step: fitting and fixing the holding jointer molds 1010 at both ends of the power supply core assembly 1040 and the pipe assemblies 1020 and 1021 so as to correspond to their lengths

3rd step: sequentially placing the pipe assembly 1022 for the common line, the power supply core assembly 1040 and the pipe assembly 1028 for the power supply line in the holding jointer molds 1010 at both sides

4th step: fitting the fixing jointer molds 1060 into the holding jointer molds 1010 to thereby fix the structural parts, and fixing the two types of molds 1010 and 1060 with the mold-fixing clips 1070

5th step: repeating the 2nd to the 4th step to correspond to a required length of the road or an amount of concrete to be poured

6th step: pouring concrete between the molds 1010 and 1060 fixing the structural parts, removing air bubbles that might be generated in the bottom portion of the power supply core assembly by using the air bubble remover 90 and flattening the top surface of the concrete

7th step: curing the poured concrete and completing the formation of the power supply apparatus

In accordance with the above-discussed forming method for the power supply apparatus, since concrete structures, arrangement of which in a construction spot needs to be under restriction, are placed and formed on a module unit, difficulty in aligning precast heavy structures can be overcome. Further, since the concrete structures are formed on the module unit, maintenance and repair work can also be carried out later on the module unit. Jointer molds are inserted between respective modules to prevent damage that might be caused by thermal expansion of the modules in their lengthwise direction. The jointer molds are plate materials made of wood such as veneer board, and they have a function as joints for absorbing thermal expansion between the modules as well as a function of dividing the modules in a lengthwise direction of the cut-out section of the road. Moreover, the jointer molds also serve to allow the internal structural parts to be arranged at designed positions and to fix those structural parts in place when concrete is poured. A section in which arrangement of structural parts is completed by using the jointer molds becomes a mold for a single power supply rail module.

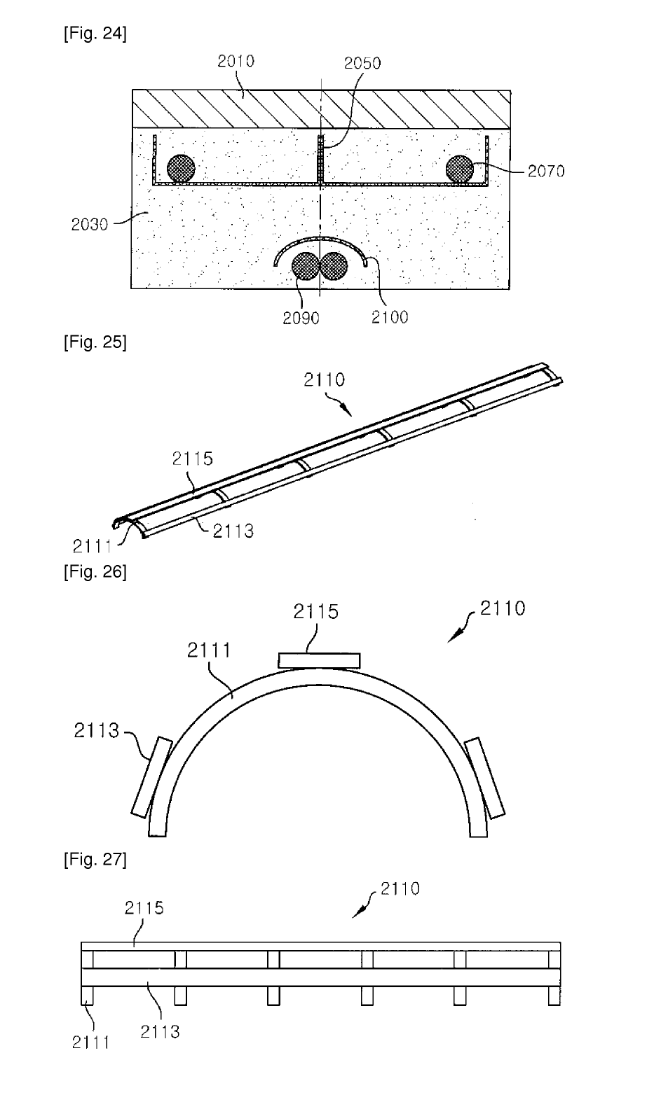

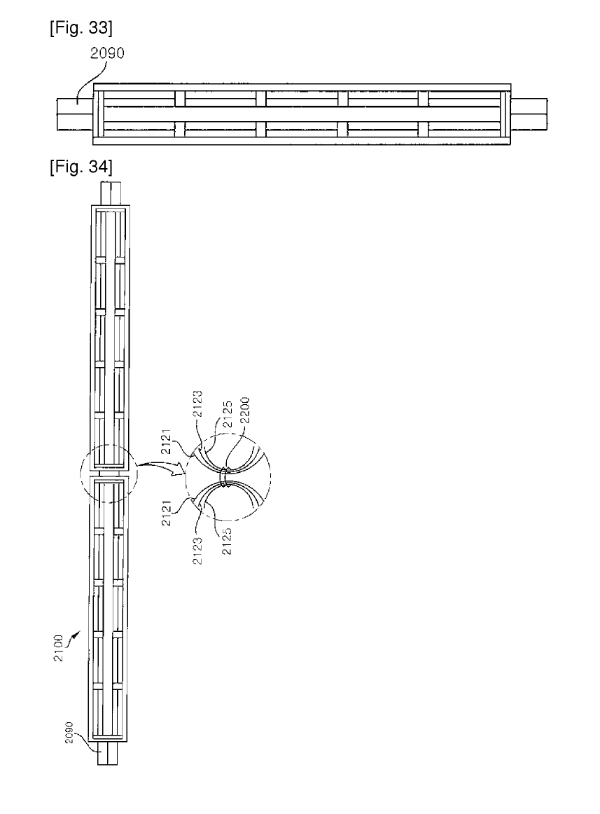

FIGS. 24 to 34 are diagrams for describing a magnetic field cancelation apparatus in accordance with an embodiment of the present invention.

FIG. 24 presents a cross sectional view of a power supply apparatus including the magnetic field cancelation apparatus in accordance with the embodiment of the present invention.

As depicted in FIG. 24, a power supply core 2050 is installed within a concrete structure 2030 under an asphalt layer 2010 as a road surface, and power supply lines 2070 are located at both peripheral sides of the concrete structure 2030 with respect to the power supply core 2050. The power supply core 2050 and the power supply lines 2070 are electrically insulated. Further, a common line 2090 is located in a central bottom portion of the concrete structure 2030 with respect to the power supply core 2050, and a magnetic field cancelation apparatus 2100 for blocking an electromagnetic field (EMF) emitted from the common line 2090 is provided directly under the common line 2090 at a certain distance maintained therebetween.

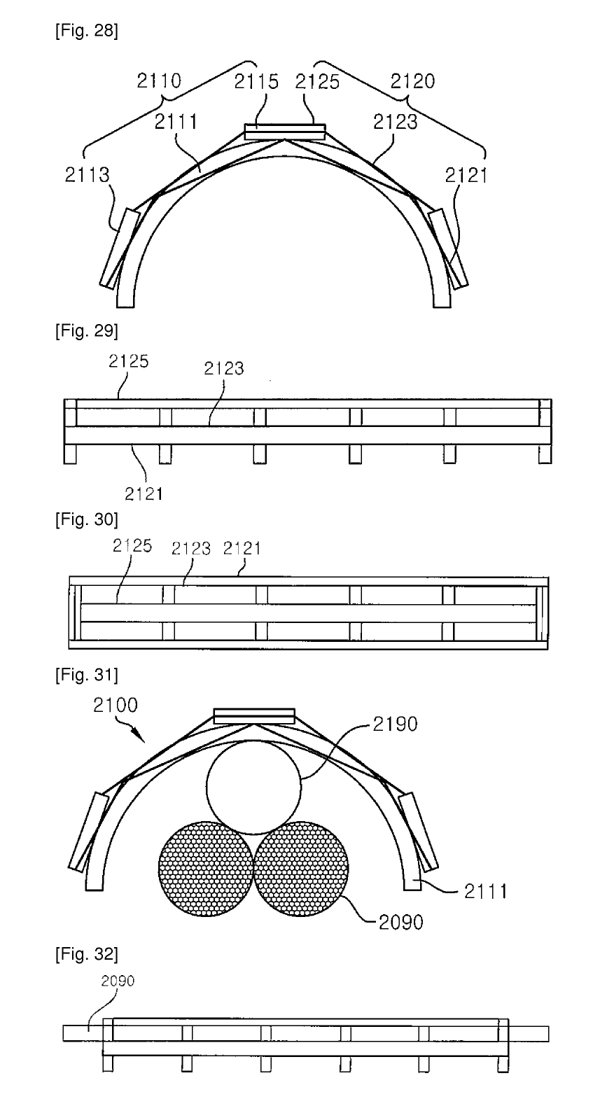

FIGS. 28 and 29 are a front view and a side view of a magnetic field cancelation apparatus 2100 in accordance with the embodiment of the present invention, respectively, and FIG. 30 is a perspective view of the magnetic field cancelation apparatus 2100.

As shown in FIGS. 28 to 30, the magnetic field cancelation apparatus includes a frame member 2110 and a coil member 2120. The frame member 2110 includes a multiple number of semicircular PVC pipes 2111, a pair of side PVC bars 2113, and a upper PVC bar 2115, and the cancelation coil 2120 includes a first coil 2121, a second coil 2123 and a third coil 2125.

FIG. 25 is a perspective view of the frame member of the magnetic field cancelation apparatus in accordance with the embodiment of the present invention, and FIGS. 26 and 27 are a front view and a side view of the frame member.

As depicted in FIGS. 25 to 27, the frame member 2110 has a stable structure including the multiple number of semicircular PVC pipes 2111 arranged in a row at a regular distance; the pair of side PVC bars 2113 arranged to connect the multiple number of semicircular PVC pipes 2111 at both side portions thereof; and the upper PVC bar 2115 placed to connect the multiple number of semicircular PVC pipes 2111 at their tops.

Referring back to FIGS. 28 to 30, the coil member 2120 installed at the frame member 2110 is a copper wire, and each of the three coils 2121, 2123 and 2125 having different lengths is configured as a closed loop. The longest coil 2121 is elongated along the bottom portions of the side PVC pars 2113 while firmly adhered to the bottom portions of the side PVC bars 2113. When the longest coil 2121 reaches the foremost and the last semicircular PVC pipe 2111, the coil 2121 is installed substantially along the circumference of the semicircular PVC pipes 2111 so as not to cross the inside of semicircles. The middle-length second coil 2123 is elongated along top portions of the side PVC bars 2113 while firmly adhered to the top portions of the side PVC bars 2113. Like the longest coil 2121, when the second coil 2123 reaches the foremost and the last semicircular PVC pipe 2111, the coil 2123 is installed substantially along the circumference of the semicircular PVC pipes 2111 so as not to cross the inside of the semicircles. The shortest coil 2125 is installed along a side surface of the upper PVC bar 2115 provided along the top of the multiple number of semicircular PVC pipes 2111.

FIGS. 31, 32 and 33 are a front view, a side view and a plane view of a magnetic field cancelation apparatus in accordance with another embodiment of the present invention, respectively.

As illustrated in FIGS. 31 to 33, a magnetic field cancelation apparatus 2100 further includes a distance-maintaining pipe 2190. To elaborate, the distance-maintaining PVC pipe 2190 for maintaining a certain distance between a common line 2090 and a semicircular PVC pipe 2111 is inserted between the common line 2090 and the semicircular PVC pipe 2211 directly above the common line 2090. With this configuration, the common line 2090 and the magnetic field cancelation apparatus 2100 are firmly fixed in place.

FIG. 34 is a plane view showing a configuration in which a multiple number of magnetic field cancelation apparatuses are installed in a row.

As shown in FIG. 34, when the length of the common line 2090 exceeds the length of a magnetic field cancelation apparatus 2100, two or more magnetic field cancelation apparatuses 2100 may be arranged in a row, and central portions of cancelation coils 2121, 2123 and 2125 located at a position (indicated in a circle of FIG. 34) where the two magnetic field cancelation apparatuses 2100 meet are put together and fixed by using, e.g., a ring-shaped insulating member 2200.

The magnetic field cancelation apparatuses 2100 described with reference to FIGS. 24 to 34 may be included in the power supply apparatuses described above with reference to FIGS. 1 to 11.

While the invention has been shown and described with respect to the embodiments, it will be understood by those skilled in the art that various changes and modifications may be made without departing from the scope of the invention as defined in the following claims.

1. A power supply apparatus for supplying power to an electric vehicle by a magnetic induction mechanism, the apparatus comprising:
a power supply structure including a multiple number of power supply rail modules connected in a forward road direction, each power supply rail module including at least one power supply line passage elongated in the forward road direction, a power supply core of a lattice structure provided below the power supply line passage, and a concrete structure incorporating the power supply line passage and the power supply core;
at least one power supply line accommodated in the power supply line passage in the forward road direction and surrounded by an insulating pipe; and
at least one common line provided in the forward road direction and surrounded by an insulating pipe, for supplying power to the power supply apparatus.

2. The power supply apparatus of claim 1, wherein the power supply core of the lattice structure includes a plurality of core blades arranged in a lattice pattern, and
a thickness of each core blade in the forward road direction is equal to or less than about ⅓ of a distance between the core blades.

3. The power supply apparatus of claim 1, wherein the common line is provided below the power supply core or at a lateral side outside the power supply core.

4. The power supply apparatus of claim 1, wherein the common line is accommodated in the concrete structure.

5. The power supply apparatus of claim 1, wherein the common line is buried outside the concrete structure.

6. The power supply apparatus of claim 1, wherein fiberglass reinforced plastic (FRP) is filled between the power supply line passage and the insulating pipe surrounding the power supply line.

7. The power supply apparatus of claim 1, further comprising:
one or more deformation absorbing members inserted in concrete structure at a regular distance in a direction perpendicular to the forward road direction, for preventing a damage due to deformation of the concrete.

8. The power supply apparatus of claim 1, further comprising:
at least one reinforcing bar installed below the power supply core in the forward road direction within the concrete structure, for reinforcing the concrete structure.

9. The power supply apparatus of claim 8, further comprising:
at least one loop current preventing steel reinforcement installed below the power supply core in a direction perpendicular to the forward road direction within the concrete structure to be distanced away at a certain distance from the steel reinforcement provided in the forward road direction, for preventing generation of a loop current by magnetic induction.

10. The power supply apparatus of claim 2, wherein each core blade has a ‘U’-shaped cross section.

11. The power supply apparatus of claim 2, wherein each core blade has a plat shape.

12. A method for forming the power supply apparatus for an electric vehicle, the method comprising:
fabricating a multiple number of power supply rail modules including at least one power supply line passage elongated in the forward road direction, a power supply core of a lattice structure provided below the power supply line passage and a concrete structure incorporating the power supply line passage and the power supply core;
forming grooves of a preset depth in a road in the forward road direction so as to accommodate the power supply rail modules in the grooves;
arranging the multiple number of power supply rail modules in the grooves one after another;
inserting at least one power supply line surrounded by an insulating pipe into the power supply line passage in the forward road direction; and
covering the power supply rail modules with asphalt.

13. The method of claim 12, wherein each power supply rail module further includes at least one common line passage elongated in the forward road direction, and
the method further comprising:
inserting said at least one common line surrounded by the insulating pipe into the common line passage before covering the power supply rail modules with asphalt.

14. The method of claim 12, wherein each power supply rail module has a ‘T’-shaped cross section, and
the method further comprising:
placing said at least one common line for supplying power to the power supply apparatus and surrounded by the insulating pipe between the power supply rail module and inner surfaces of the groove before placing the power supply rail module in the groove.

15. A method for forming a power supply apparatus for an electric vehicle, the power supply apparatus including at least one power supply line, a power supply core assembly and at least one common line, the method comprising:
forming a cut-out section of a certain width and a certain depth in a road;
installing a power supply rail module including a power supply line pipe for accommodating the power supply line, the power supply core assembly and a common line pipe for accommodating the common line;
installing a multiplicity of power supply rail modules in the cut-out section in a forward road direction by repeating the process of installing the power supply rail module; and
pouring and curing concrete in the power supply rail modules.

16. The method of claim 15, wherein the process of installing each power supply rail module in the cut-out section includes:
installing a pair of holding jointer molds, each of which is provided with grooves in a first direction for holding the power supply pipe, the power supply core assembly and the common line pipe;
holding the power supply pipe, the power supply core assembly and the common line pipe on the pair of holding jointer molds;
fitting a pair of fixing jointer molds, each of which is provided with grooves in an opposite direction to the first direction for fixing the power supply pipe, the power supply core assembly and the common line pipe, onto the holding jointer molds; and
fixing the holding jointer mold and the fixing jointer mold by using a mold-fixing clip.

17. A magnetic field cancelation apparatus for a power supply apparatus for an electric vehicle, the power supply apparatus including at least one power supply line buried in a road and elongated in a lengthwise direction of the road, a power supply core provided below the power supply line while being electrically insulated from the power supply line, and a common line provided below the power supply core, the magnetic field cancelation apparatus comprising:
a frame member; and
a coil member having a plurality of coils, each coil being wound around the frame member and forming a closed loop,
wherein the magnetic field cancelation apparatus is placed on the common line to cancel an electromagnetic field emitted from the common line.

18. The magnetic field cancelation apparatus of claim 17, further comprising:
a fixing member inserted between the common line and the frame member, for maintaining a distance between the common line and the frame member.

19. The magnetic field cancelation apparatus of claim 17, wherein the frame member includes:
a multiple number of semicircular members arranged in a row, each of the semicircular members having a semicircular cross section;
a pair of side connecting members arranged to connect both side portions of the multiple number of semicircular members; and
an upper connecting member provided to connect top portions of the multiple number of semicircular members.

20. The magnetic field cancelation apparatus of claim 17, wherein the coil member include:
a first coil elongated along bottom portions of the side connecting members while being firmly adhered to the bottom portions of the side connecting members, and installed substantially along the circumference of each of the foremost and the last semicircular member so as not to cross the inside of semicircles;
a second coil elongated along a top portion of the side connecting members while being firmly adhered to the top portions of the side connecting members, and installed substantially along the circumference of each of the foremost and the last semicircular member so as not to cross the inside of the semicircles; and
a third coil installed along aside surface of the upper connecting member.
